(19) United States
(12) Patent Application Publication
(10) Pub. No.: US 2021/0207259 A1
(43) Pub. Date: Jul. 8, 2021

(54) EVAPORATION SOURCE DEVICE AND EVAPORATION COATING EQUIPMENT

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventor: Jian LI, Beijing (CN)

(21) Appl. No.: 16/072,257

(22) PCT Filed: Dec. 15, 2017
(86) PCT No.: PCT/CN2017/116533

§ 371 Date: Jul. 24, 2018

(30) Foreign Application Priority Data
Feb. 15, 2017 (CN) 201720135353.1

(51) Int. Cl. C23C 14/24; C23C 14/54

(52) U.S. Cl. CPC C23C 14/243; C23C 14/54

(57) ABSTRACT

An evaporation source device includes: a support, a group of nozzles and a housing disposed on the support; the housing includes an evaporation opening, so that the evaporation material sprayed from the group of nozzles passes through the evaporation opening. An evaporation coating equipment also disclosed.

### CROSS-REFERENCE OF RELATED APPLICATION

The present application claims the priority of Chinese patent application No. 201720135353.1 filed on Feb. 15, 2017, the disclosure of which is hereby incorporated by reference herein in its entirety.

### TECHNICAL FIELD

Embodiments of the present disclosure relate to an evaporation source device and an evaporation coating equipment.

### BACKGROUND

OLED displays comprise PMOLED (Passive Matrix Organic Light-Emitting Diode) display and AMOLED (Active Matrix Organic Light-Emitting Diode) display.

### SUMMARY

At least one of the embodiments provides an evaporation source device, comprising: a support; a group of nozzles and a housing both disposed on the support; wherein the housing comprises an evaporation opening, so that an evaporation material sprayed from the group of nozzles passes through the evaporation opening.

For example, in the evaporation source device provided by at least one of the embodiments, the housing comprises at least two plates disposed opposite to each other, the at least two plates are disposed on opposite sides of the group of nozzles to form the evaporation opening in a spray direction of the group of nozzles.

For example, in the evaporation source device provided by at least one of the embodiments, the housing comprises four plates, the four plates surrounds the group of nozzles to form the evaporation opening in the spray direction of the group of nozzles.

For example, in the evaporation source device provided by at least one of the embodiments, a plate comprises a heating element.

For example, in the evaporation source device provided by at least one of the embodiments, the plate comprises a cavity, the heating element is disposed in the cavity.

For example, in the evaporation source device provided by at least one of the embodiments, the heating element is at least one of an electric heating element and a microwave heating element.

For example, in the evaporation source device provided by at least one of the embodiments, a protection layer is disposed on a side of a plate toward the group of nozzles.

For example, in the evaporation source device provided by at least one of the embodiments, a material of the protection layer is at least one of ceramic and metal.

For example, in the evaporation source device provided by at least one of the embodiments, a cooling plate is disposed on a side of a plate away from the group of nozzles.

For example, in the evaporation source device provided by at least one of the embodiments, the cooling plate is provided with a coolant.

For example, in the evaporation source device provided by at least one of the embodiments, an angle of a plate with respect to the spray direction of the group of nozzles is adjustable.

For example, in the evaporation source device provided by at least one of the embodiments, an end of a plate is flexibly connected with an outer wall of the support.

For example, in the evaporation source device provided by at least one of the embodiments, the end of the plate is pivotally connected with the outer wall of the support, so that the end of the plate is rotated around a joint.

For example, in the evaporation source device provided by at least one of the embodiments, the group of nozzles comprises a plurality of nozzles.

For example, in the evaporation source device provided by at least one of the embodiments, a nozzle is a linear nozzle.

At least one of the embodiments provides an evaporation coating equipment, comprising any one of the above evaporation source devices.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 schematically illustrates an evaporation source device during evaporation;

FIG. 2 schematically illustrates an evaporation source device provided by an embodiment of the present disclosure;

FIG. 3a schematically illustrates an evaporation source device during evaporation provided by an embodiment of the present disclosure;

FIG. 3b schematically illustrates another evaporation source device during evaporation provided by an embodiment of the present disclosure;

FIG. 4 schematically illustrates a plate provided by an embodiment of the present disclosure;

FIG. 5 schematically illustrates an evaporation source device provided by another embodiment of the present disclosure;

FIG. 6 schematically illustrates a plate and a cooling plate provided by an embodiment of the present disclosure;

FIG. 7 schematically illustrates an evaporation source device during evaporation provided by another embodiment of the present disclosure;

FIG. 8 schematically illustrates the plates of an evaporation source device being opened accordingly to an embodiment of the present disclosure; and

FIG. 9 schematically illustrates a block diagram of an evaporation coating equipment provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

It is noted that, the shapes and sizes of the components in the drawings are only intended to schematically illustrate the present disclosure, but not to represent the actual proportions.

An AMOLED display comprises two implementations, one of the two implementations is a combination of a low temperature polysilicon (LTPS) back plate and a fine metal mask (FMM Mask), and another is a combination of an oxide back plate, a white organic light-emitting diode (WOLED) and a color filter.

In the first implementation, an OLED luminescent material is evaporated onto the LTPS back plate by evaporation, and a red, green, blue light-emitting device is formed by using a pattern of the FMM.

The light-emitting layer is typically made of two or more luminescent materials. While multiple materials are evaporated onto the glass substrate, in order to ensure that the profiles of different luminescent materials coincide with one another without layer lamination, separate plates are disposed on top of a conventional linear evaporation source to control an evaporation angle of the evaporation material. As a result, different evaporation materials are sprayed from different nozzles, leave from their respective spaces, mixed in the evaporation chamber, and then reach the glass substrate.

However, in the above evaporation device, the profile coincidence of multiple materials is poor and the performance of the product is poor. Moreover, a large amount of evaporation materials leaves on the plates, which results in large waste, thus the utilization of the materials is low; additionally, the materials fall off from the plates blocks the nozzle of the crucible, so it is necessary to periodically replace or clean the plates, which leads to tedious routine cleansing and maintenance.

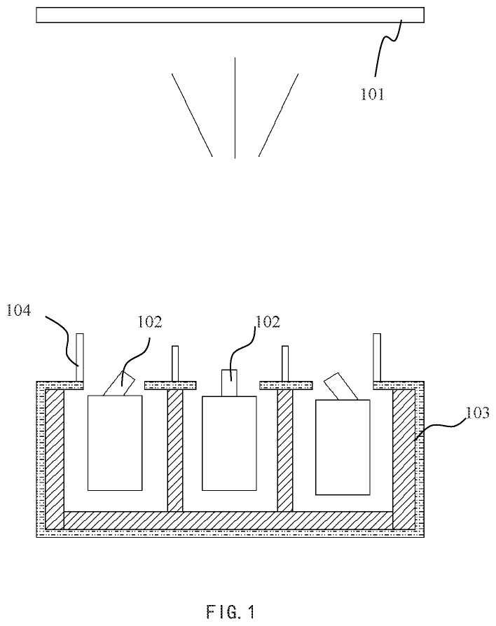

FIG. 1 schematically illustrates an evaporation source device during evaporation. As illustrated in FIG. 1, a plate 104 is disposed at an outlet of each group of nozzles 102 of crucible, a cooling wall 103 is disposed on an outside of the crucible; different materials are evaporated from respective spaces enclosed by plates 104 and reached a glass substrate 101 after being mixed. However, when the evaporation source device illustrated in FIG. 1 is in use, the profile consistency of multiple materials is not good, which would result in layer laminations formed on a surface of the glass substrate.

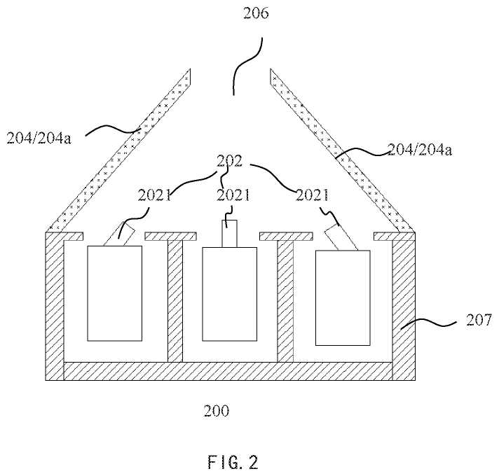

FIG. 2 schematically illustrates an evaporation source device provided by an embodiment of the present disclosure. As illustrated in FIG. 2, the evaporation source device 200 comprises a support 207, a group of nozzles 202 and a housing 204 both disposed on the support 207; the housing 204 comprises an evaporation opening 206, so that the evaporation material sprayed from the group of nozzles 202 passes through the evaporation opening 206.

It is noted that, the housing 204 may be a plate-shaped structure disposed opposite to each other, or may be a cone-shaped structure with openings at the top and bottom, which may be a structure with a large upper opening and a small lower opening, or may be a structure with a small upper opening and a large lower opening.

For example, the housing 204 comprises at least two plates, which are disposed opposite to each other. For example, the number of the plates may be two, three, four, five, six, etc.

It is noted that, in embodiments of the present disclosure, the plate is a planar component whose thickness is much smaller than a length or a width of the surface of the plate, and the plate is made of a rigid material. For example, the cone-shaped structure with openings at the top and bottom are formed by at least such two plates which are disposed opposite to each other.

As illustrated in FIG. 2, the housing 204 comprises two plates 204 which are disposed opposite to each other, the two plates 204 are disposed on two opposite sides of the group of nozzles 202, and the evaporation opening 206 is formed in spray direction of the group of nozzles 202.

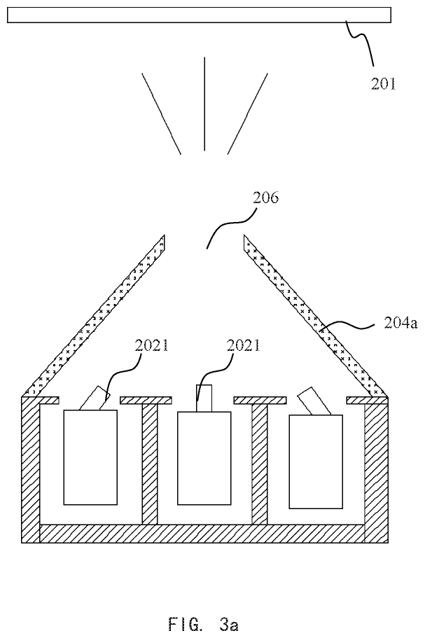

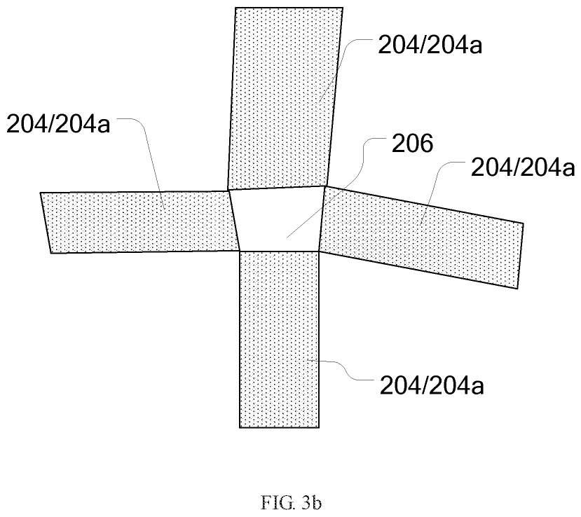

For example, FIG. 3a schematically illustrates an evaporation source device during evaporation provided by an embodiment of the present disclosure. For example, during evaporation, different materials are respectively sprayed from the group of nozzles 202, and uniformly mixed in a space enclosed by plates 204a, so that the evaporation materials are finally sprayed from a same evaporation opening 206, and reach a glass substrate 201, thus the layer lamination on the surface of the glass substrate which is caused by poor profile consistency of multiple materials can be avoided, and the problem of poor profile consistency of multiple materials can be solved.

For example, the group of nozzles 202 comprises a plurality of nozzles 2021, the plates 204a are disposed on at least two opposite sides of the group of nozzles 202, so as to form an evaporation opening 206 on the top of the group of nozzles 202.

For example, the group of nozzles 202 is a group of linear nozzles, a plurality of nozzles 2021 are a plurality of linear nozzles, which are disposed along a direction of line source. The evaporation materials such as organic materials used for forming a light-emitting layer are sprayed from each linear nozzle 2021, and deposited on the glass substrate 201 through the same evaporation opening 206.

For example, FIG. 3b schematically illustrates another evaporation source device during evaporation provided by an embodiment of the present disclosure. In another embodiment, as illustrated in FIGS. 3a and 3b, the housing 204 comprises four plates 204a, which are respectively disposed around the group of nozzles 202, so as to form an evaporation opening 206 in the spray direction of the group of nozzles 202.

For example, different materials are sprayed from the group of nozzles 202, and uniformly mixed between the plates 204a, so that the evaporation materials are finally sprayed from the same evaporation opening 206, and reach the glass substrate 201. The evaporation source device can make materials be mixed inside the evaporation source (between the plates) effectively and uniformly, and make evaporation materials be sprayed from the same evaporation opening 206, thus the layer lamination on the surface of the glass substrate which is caused by poor profile consistency of multiple materials can be avoided, and then the problem of poor profile consistency of multiple materials can be solved.

In another embodiment of the present disclosure, the plate 204a further comprises a heating element. For example, the heating element is disposed in the space enclosed by the plates 204a, which is configured to keep the evaporation materials at a temperature while being sprayed, or to increase the temperature of evaporation materials. For example, the heating element is disposed on the plate 204a, which can increase the temperature of the plate. By controlling the temperature of the plate under an appropriate temperature, the condensation of a large mount of evaporation materials on the plate can be avoided, the waste caused by adhesion of evaporation materials to the plate can be reduced, so that more evaporation materials can be sprayed through the evaporation opening and reach the surface of the glass substrate, then the problem of low utilization of evaporation material can be solved.

It is noted that, in order to ensure that the evaporation materials cannot be adhered to the plate or be wasted, the temperature of the plate is higher than the evaporation temperature of the materials, and meanwhile, the temperature of the plate is lower than decomposition temperature of evaporation materials, such that the evaporation materials cannot be decomposed due to high temperature. The heating element may be disposed on the surface of the plate, or may be disposed inside the plate, as long as the temperature of the plate can be controlled.

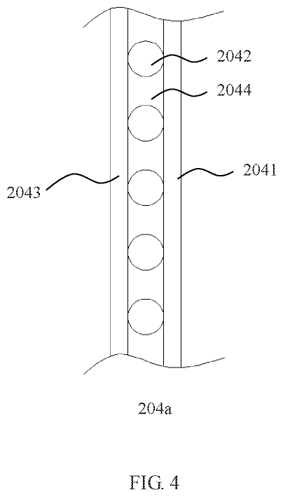

For example, FIG. 4 schematically illustrates a plate of the evaporation source device provided by an embodiment of the present disclosure. For example, the plate 204a comprises a cavity, and the heating element 2042 is disposed in the cavity 2044. Because the plate 204a comprises the cavity 2044, and the heating element 2042 is disposed in the cavity 2044, it is ensured that the contact temperature between the entire plate and evaporation materials is uniform, the decomposition of evaporation materials due to local overheating or the adhesion and accumulation of evaporation materials on the plate due to local overcooling cannot occur. Therefore, the evaporation source device provided in embodiments of the present disclosure not only increases the utilization of evaporation materials, but also reduces the frequency of replacement or cleansing of the plates.

For example, the heating element 2042 is at least one selected from an electric heating element and a microwave heating element, for example, the heating element comprises a heating wire or a golden heating plate or the like. The heating elements 2042 heat the plate 204a to increase its temperature. For example, the number of heating elements 2042 is multiple.

It is noted that, the arrangement of the heating element 2042 is not limited to that shown in FIG. 4; the heating element 2042 may be evenly or unevenly distributed in the plate. Providing a plurality of plates 2042 makes the contact temperature between the entire plate and evaporation materials uniform, the decomposition of evaporation materials due to local overheating or the adhesion and accumulation of evaporation materials on the plate due to local overcooling cannot occur.

For example, a protection layer 2041 is disposed on a side of the plate 204a toward the group of nozzles 202, and the material of the protection layer 2041 is at least one of ceramic and metal. Thus, chemical or physical reaction between evaporation materials and the side of the plate 204a on which the protection layer 2041 is disposed can be avoided, and the contact temperature between the entire plate 204a and evaporation material can be ensured to be uniform. The heating element 2042 is configured for at least heating one side of the plate 204a toward the group of nozzles 202.

For example, as illustrated in FIG. 4, the plate 204a further comprises a side 2043 away from the group of nozzles 202.

For example, FIG. 5 schematically illustrates another evaporation source device provided by another embodiment of the present disclosure. A cooling plate 205 is disposed on the side of the plate 204a away from the group of nozzles 202. Since the cooling plate 205 is disposed on the side of the plate 204a away from the group of nozzles 202, and the cooling plate 205 has a cooling function, the heat radiation to the glass substrate 201 or to the mask due to the excessive temperature of the plate 204a can be avoided, and the problem of uneven film formation due to excessive temperature can be solved.

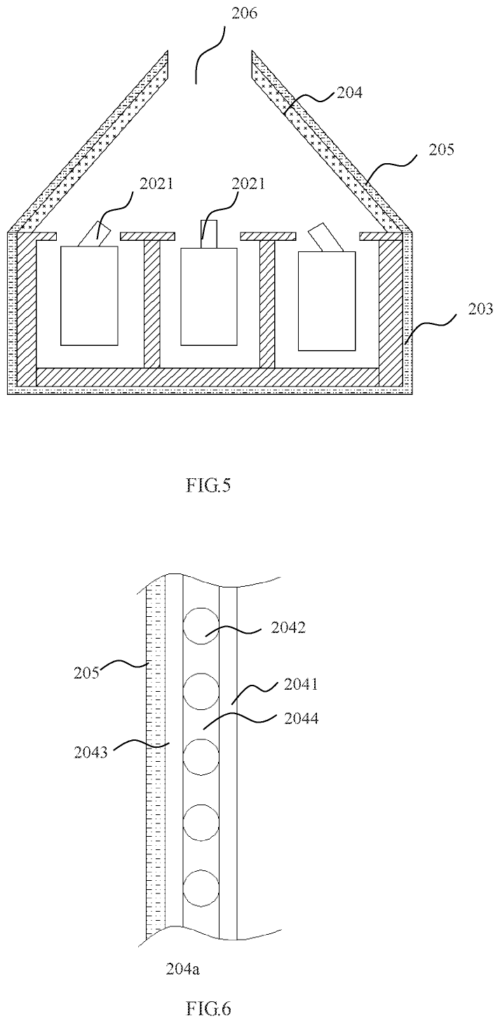

For example, FIG. 6 schematically illustrates a plate and a cooling plate of the evaporation source device provided by an embodiment of the present disclosure. For example, the plate 204a comprises a cavity 2044 in which a heating element 2042 is disposed. One side 2041 of the plate 204a is toward the group of nozzles 202, the other side 2043 of the plate 204a is away from the group of nozzles 202, the cooling plate 205 is disposed on the side 2043 away from the group of nozzles 202, and the heating element 2042 is configured at least for heating the side 2041 of the plate 204a toward the group of nozzles 202.

For example, the cooling plate 205 is disposed along the surface of the plate 204a and on the side 2043 away from the group of nozzles 202, an evaporation opening 206 is formed at the top of the group of nozzles 202. The plate 204a and the cooling plate 205 may be attached to each other, and also may be separated from each other by a certain distance. A surface area of the cooling plate 205 may be the same as the surface area of the plate 204a, or they are different from each other. That is, the arrangement of the cooling plate 205 is not limited to the embodiments, as long as the cooling plate 205 does not shield the evaporation opening 206.

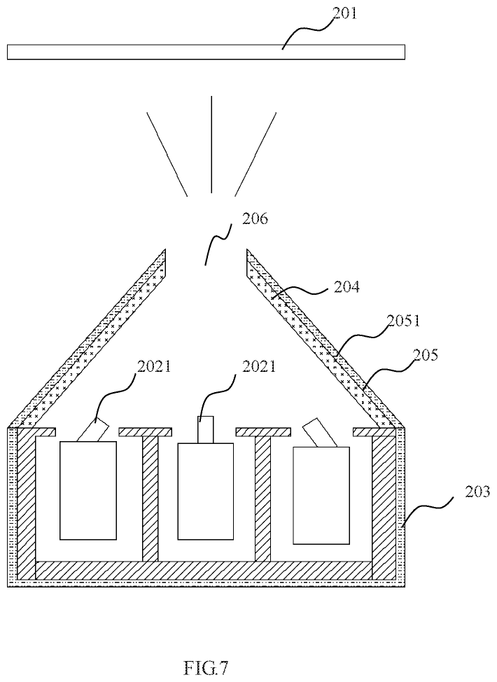

For example, FIG. 7 schematically illustrates another evaporation source device during evaporation provided by another embodiment of the present disclosure. Because the cooling plate 205 is disposed on the plate 204a, different materials are sprayed from the group of nozzles 202, mixed uniformly between the plates 204a, finally leave from the same evaporation opening 206, and reach the glass substrate 201. Thus the heat radiation to the glass substrate 201 or to the mask due to excessive temperature of the plate 204a can be avoided.

For example, the interior of the cooling plate 205 is in communication with the circulating cooling water, the cooling plate 205 is cooled by the circulating cooling water and therefore has a cooling function, in this way, the heat radiation to the glass substrate or the mask due to excessive temperature of the plate 204a can be avoided, and the problem of uneven film formation due to excessive temperature can be solved. For example, the interior of the cooling plate 205 is filled with a coolant 2051 which is configured for cooling the cooling plate 205, thus the cooling plate 205 has a cooling function.

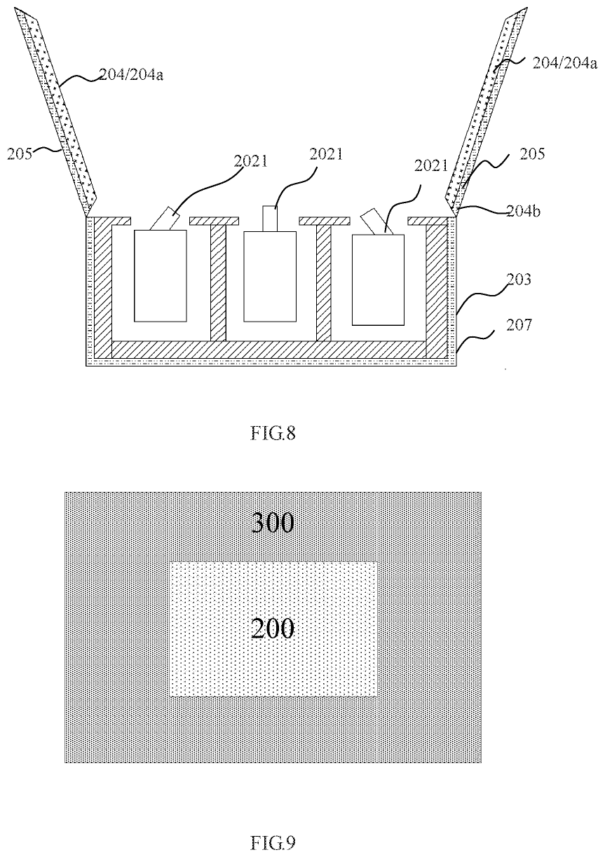

For example, the angle of the plate 204a with respect to the spray direction of the group of nozzles is adjustable, that is, the opening and closing angles of the plate 204a are adjustable. FIG. 8 schematically illustrates an evaporation source device while the plates are open according to an embodiment of the present disclosure. Because the opening and closing angles of the plate 204a are adjustable, on one hand, the size and angle of the evaporation opening may be variable, thus, the size of evaporation region may be variable; on the other hand, the group of nozzles may be exposed, thus it is easy to cleanse the plates and nozzles. It is noted that, in order to adjust the opening and closing angles of the plates, the opening and closing angles of the cooling plate may also be adjustable.

For example, an end 204b of the plate 204a is flexibly connected with the outer wall 203 of the support 207. For example, the end 204b of the plate 204a is pivotally connected with the outer wall of the support 207, so that the end 204b of the plate 204a is rotated around the joint. For example, the flexibly connection may also be hinge connection. Therefore, the opening and closing angles of the plates can be adjusted as required, which is not only convenient for changing the size and angle of evaporation opening, but also convenient for cleansing the plates and nozzles.

At least one embodiment of the present disclosure further provides an evaporation coating equipment, which comprises the evaporation source device provided in any of the above embodiments.

For example, FIG. 9 schematically illustrates a block diagram of an evaporation coating equipment provided by an embodiment of the present disclosure. As illustrated in FIG. 9, the evaporation coating equipment 300 comprises an evaporation source device 200, the implementation and working principle of the evaporation source device 200 may be referred to the related description in above embodiments.

The evaporation source device and evaporation coating equipment provided in embodiments of the present disclosure have at least one of the following advantageous effects:

(1) In the evaporation source device provided in at least one embodiment of the present disclosure, the multiple separated plates are replaced with the plates which are configured to form an evaporation opening, in this way, the multiple evaporation materials can be sprayed from the same evaporation opening and deposited on the glass substrate.

(2) In the evaporation source device provided in at least one embodiment of the present disclosure, it is possible to ensure that multiple evaporation materials are more uniformly mixed in the space enclosed by the plates, so that the layer lamination due to the different evaporation angles cannot be formed on the glass substrate, the profile consistence of layers is increased (>80%), and the device efficiency is increased.

(3) In the evaporation source device provided in at least one embodiment of the present disclosure, because the temperature of the plates is controllable, by increasing the temperature of the plates, the condensation of a large amount of evaporation materials on the plates can be avoided, and the waste caused by adhesion of evaporation materials to the plates can be reduced, so that much more materials can be sprayed through the evaporation opening and reach the glass substrate. The utilization of materials is increased.

(4) In the evaporation source device provided in at least one embodiment of the present disclosure, the problem that the angle of the plate is changed due to the plate adsorbing evaporation material for a long time can be avoided, and the problem that the nozzle of the crucible is blocked by excessive materials accumulation can also be avoided.

In the present disclosure, the following should be noted:

(1) The accompanying drawings involve only the structure(s) in connection with the embodiment(s) of the present disclosure, and other structure(s) can be referred to common design(s).

(2) For the purpose of clarity only, in accompanying drawings for illustrating the embodiment(s) of the present disclosure, the thickness and a size of a layer or area may be enlarged or reduced, that is, the drawings are not drawn in a real scale. It should be understood that, when an element such as a layer, film, region or substrate is referred to as being “on” or “under” another element, it can be disposed “directly on” or “directly below” another element, or there may be intermediate element(s).

(3) In case of no conflict, features in one embodiment or in different embodiments can be combined as a new embodiment.

What is described above is related to the illustrative embodiments of the disclosure only and not limitative to the scope of the disclosure; the scopes of the disclosure are defined by the accompanying claims.

1. An evaporation source device, comprising:
a support;
a group of nozzles and a housing both disposed on the support;
wherein the housing comprises an evaporation opening, so that an evaporation material sprayed from the group of nozzles passes through the evaporation opening.

2. The evaporation source device according to claim 1, wherein the housing comprises at least two plates disposed opposite to each other, the at least two plates are disposed on opposite sides of the group of nozzles to form the evaporation opening in a spray direction of the group of nozzles.

3. The evaporation source device according to claim 2, wherein the housing comprises four plates, the four plates surrounds the group of nozzles to form the evaporation opening in the spray direction of the group of nozzles.

4. The evaporation source device according to claim 2, wherein a plate comprises a heating element.

5. The evaporation source device according to claim 4, wherein the plate comprises a cavity, the heating element is disposed in the cavity.

6. The evaporation source device according to claim 4, wherein the heating element is at least one of an electric heating element and a microwave heating element.

7. The evaporation source device according to claim 2, wherein a protection layer is disposed on a side of a plate toward the group of nozzles.

8. The evaporation source device according to claim 7, wherein a material of the protection layer is at least one of ceramic and metal.

9. The evaporation source device according to claim 2, wherein a cooling plate is disposed on a side of a plate away from the group of nozzles.

10. The evaporation source device according to claim 9, wherein the cooling plate is provided with a coolant.

11. The evaporation source device according to claim 2, wherein an angle of a plate with respect to the spray direction of the group of nozzles is adjustable.

12. The evaporation source device according to claim 2, wherein an end of a plate is flexibly connected with an outer wall of the support.

13. The evaporation source device according to claim 12, wherein the end of the plate is pivotally connected with the outer wall of the support, so that the end of the plate is rotated around a joint.

14. The evaporation source device according to claim 2, wherein the group of nozzles comprises a plurality of nozzles.

15. The evaporation source device according to claim 14, wherein a nozzle is a linear nozzle.

16. An evaporation coating equipment, comprising: an evaporation source device according to claim 1.

17. The evaporation coating equipment according to claim 16, wherein the housing comprises at least two plates disposed opposite to each other, the at least two plates are disposed on opposite sides of the group of nozzles to form the evaporation opening in a spray direction of the group of nozzles.

18. The evaporation coating equipment according to claim 16, wherein the housing comprises four plates, the four plates surrounds the group of nozzles to form the evaporation opening in the spray direction of the group of nozzles.

19. The evaporation coating equipment according to claim 16, wherein a plate comprises a heating element.

20. The evaporation coating equipment according to claim 16, wherein a cooling plate is disposed on a side of a plate away from the group of nozzles.
